(19) United States
(12) Patent Application Publication
(10) Pub. No.: US 2013/0137357 A1
(43) Pub. Date: May 30, 2013

(54) CONTAINER DATA CENTER AND METHOD FOR CONTROLLING AIRFLOW INTO THE CONTAINER DATA CENTER

(71) Applicants: YAO-TING CHANG, Tu-Cheng (TW); CHAO-KE WEI, Tu-Cheng (TW)

(72) Inventors: YAO-TING CHANG, Tu-Cheng (TW); CHAO-KE WEI, Tu-Cheng (TW)

(73) Assignee: HON HAI PRECISION INDUSTRY CO., LTD., Tu-Cheng (TW)

(21) Appl. No.: 13/337,078

(22) Filed: Dec. 24, 2011

(30) Foreign Application Priority Data
Nov. 28, 2011 (TW) 100143490

(51) Int. Cl. H05K 5/02

(52) U.S. Cl. 454/184

(57) ABSTRACT

A container data center includes a portable container, a number of server cabinets accommodated in the container, a shutter set on a side wall of the container, a temperature sensor to sense a temperature of air outside the container, a humidity sensor to sense a humidity of air outside the container, and a controlling device to receive the sensed temperature and the sensed humidity. The controlling device compares the sensed temperature with a preset temperature and compares the sensed humidity with a preset humidity range. When the sensed temperature is less than the preset temperature and the sensed humidity is in the preset humidity range, the controlling device opens the shutter. When the sensed temperature is higher than the preset temperature or the sensed humidity is outside of the preset humidity range, the controlling device closes the shutter.

### BACKGROUND

1. Technical Field

The present disclosure generally relates to a container data center and a method for controlling airflow into the container data center.

2. Description of Related Art

Container data centers usually use air conditioners to dissipate heat. The air conditioners consume great amount of energy. If air outside the container data center can enter the container data center, the air can lower the temperature inside the container data container and saves power.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a schematic view of an exemplary embodiment of a container data center.

FIG. 2 is a block diagram of the container data center of FIG. 1.

FIG. 3 is a flowchart of an exemplary embodiment of a method for controlling airflow into a container data center.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean at least one.

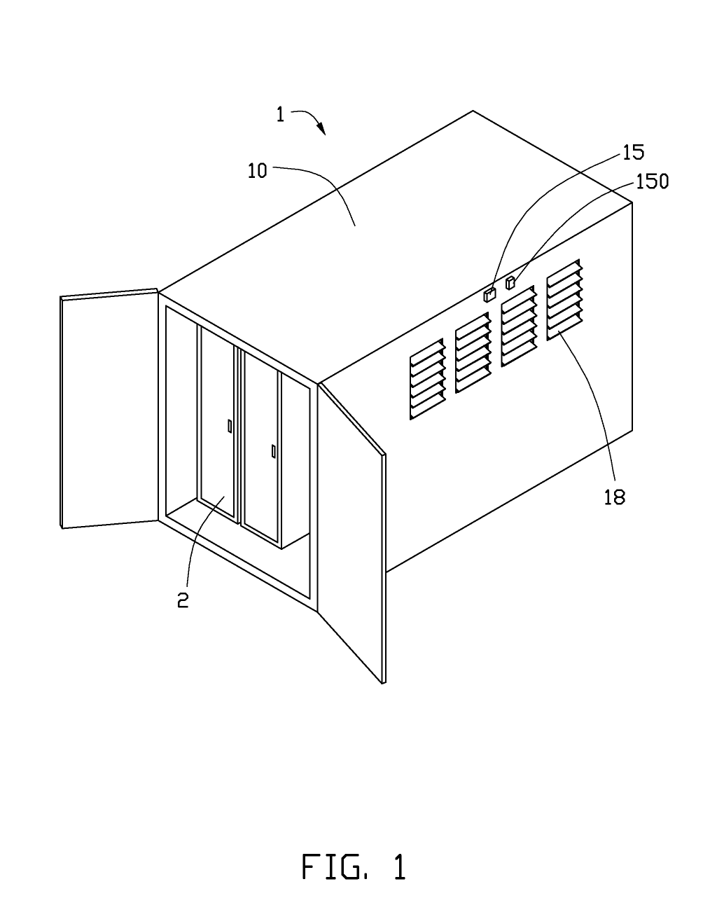

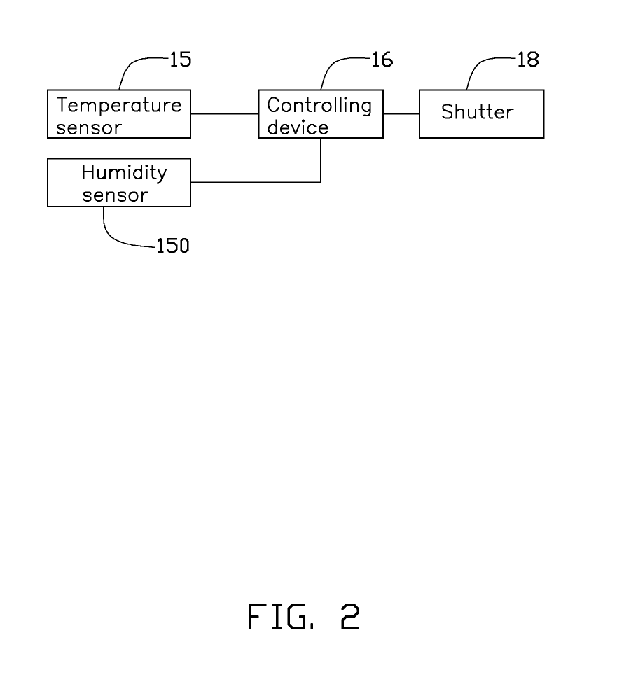

Referring to FIG. 1 and FIG. 2, an exemplary embodiment of a container data center 1 includes a portable container 10, a plurality of server cabinets 2 accommodated in the container 10, a temperature sensor 15, a humidity sensor 150, a controlling device 16 connected to the temperature sensor 15 and the humidity sensor 150, and a plurality of shutters 18 connected to the controlling device 16.

The shutters 18 are set on the side walls of the container 10. When the shutters 18 are open, air outside of the container data center 1 can enter the container 10. The controlling device 16 is set inside the container 10 to open or close the shutters 18.

The temperature sensor 15 and the humidity sensor 150 are set on outer surfaces of the container 10 and close to the shutters 18. The temperature sensor 15 senses a temperature of air near the shutters 18. The humidity sensor 150 senses a humidity of air near the shutters 18. The controlling device 16 receives the temperature and humidity sensed by the sensors 15 and 150, and compares the temperature and humidity respectively with a preset temperature and a preset humidity range. When the temperature sensed by the temperature sensor 15 is less than the preset temperature and the humidity sensed by the humidity sensor 150 is in the preset humidity range, the controlling device 16 opens the shutters 18, such that the air outside the container 10 enters the container 10. In this embodiment, the preset temperature is 25 degrees celsius, and the preset humidity range is 40% to 80%. When the sensed temperature is less than 25 degrees celsius and the sensed humidity is in 40%-80%, the controlling device 16 opens the shutters 18. As a result, air outside the container 10 enters the container 10 to dissipate heat inside the container 10.

When the temperature sensed by the temperature sensor 15 is higher than the preset temperature, or the humidity sensed by the humidity sensor 150 is outside of the preset humidity range, the controlling device 16 closes the shutters 18, such that the air outside the container 10 cannot enter the container 10.

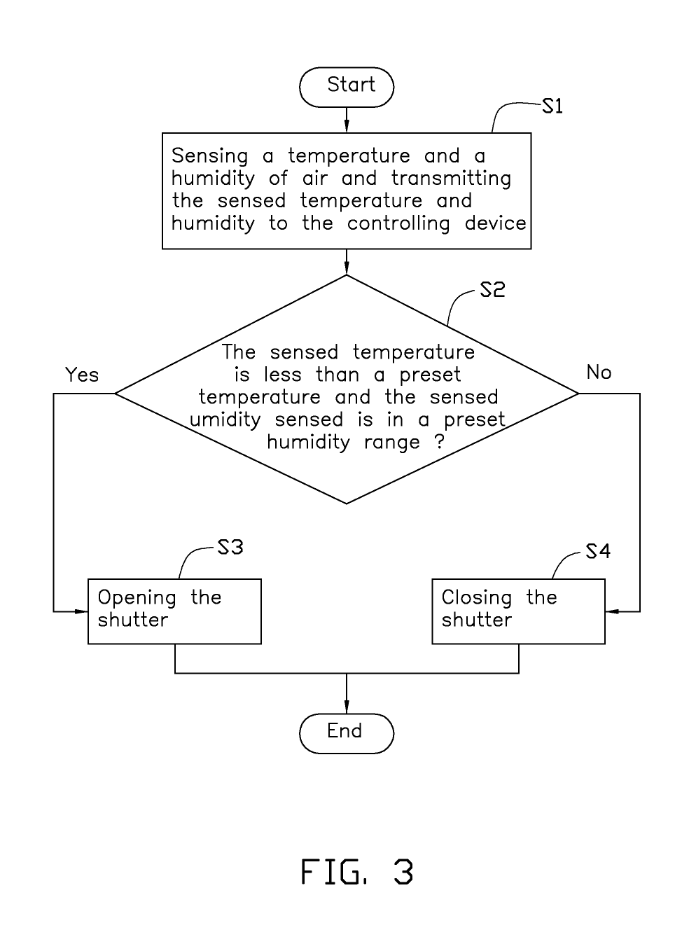

Referring to FIG. 3, an exemplary embodiment of a method for controlling airflow into the container data center 1 includes the following steps.

In step S1, the temperature sensor 15 senses a temperature of air outside the container 10 and transmits the sensed temperature to the controlling device 16, and the humidity sensor 150 senses a humidity of air outside the container 10 and transmits the sensed humidity to the controlling device 16.

In step S2, the controlling device 16 determines whether the temperature sensed by the temperature sensor 15 is less than a preset temperature and whether the humidity sensed by the humidity sensor 150 is in a preset humidity range. If the temperature sensed by the temperature sensor 15 is less than the preset temperature and the humidity sensed by the humidity sensor 150 is in the preset humidity range, the procedure flows to step S3. If the temperature sensed by the temperature sensor 15 is higher than the preset temperature or the humidity sensed by the humidity sensor 150 is outside of the preset humidity range, the procedure flows to step S4.

In step S3, the controlling device 16 opens the shutters 18, such that air outside the container 10 can enter the container 10.

In step S4, the controlling device 16 closes the shutters 18, such that air outside the container 10 cannot enter the container 10.

The foregoing description of the exemplary embodiments of the disclosure has been presented only for the purposes of illustration and description and is not intended to be exhaustive or to limit the disclosure to the precise forms disclosed. Many modifications and variations are possible in light of everything above. The embodiments were chosen and described in order to explain the principles of the disclosure and their practical application so as to enable others of ordinary skill in the art to utilize the disclosure and various embodiments and with various modifications as are suited to the particular use contemplated. Alternative embodiments will become apparent to those of ordinary skills in the art to which the present disclosure pertains without departing from its spirit and scope. Accordingly, the scope of the present disclosure is defined by the appended claims rather than the foregoing description and the exemplary embodiments described therein.

What is claimed is:

1. A container data center comprising:
a portable container;
a plurality of server cabinets accommodated in the container;
at least one shutter set on walls of the container;
a temperature sensor set outside the container to sense a temperature of air outside the container;
a humidity sensor set outside the movable container to sense a humidity of air outside the container; and
a controlling device to receive the sensed temperature and the sensed humidity, and compare the sensed temperature with a preset temperature and compare the sensed humidity with a preset humidity range, wherein when the sensed temperature is less than the preset temperature and the sensed humidity is in the preset humidity range, the controlling device opens the at least one shutter, when the sensed temperature is higher than the preset temperature or the sensed humidity is outside of the preset humidity range, the controlling device closes the at least one shutter.

2. The container data center of claim 1, wherein the temperature sensor is positioned close to the at least one shutter.

3. The container data center of claim 1, wherein the humidity sensor is positioned close to the at least one shutter.

4. The container data center of claim 1, wherein the preset temperature is 25 degrees celsius, and the preset humidity range is 40%-80%.

5. A method for controlling airflow into a container data center, the container data center comprising a portable container, a temperature sensor, a humidity sensor, at least one shutter, and a controlling device, the method comprising:
sensing a temperature of air outside the container through the temperature sensor and transmitting the sensed temperature to the controlling device;
sensing a humidity of air outside the container through the humidity sensor and transmitting the sensed humidity to the controlling device;
comparing the sensed temperature with a preset temperature and comparing the sensed humidity with a preset humidity range, through the controlling device;
opening the at least one shutter through the controlling device when the sensed temperature is less than the preset temperature and the sensed humidity is in the preset humidity range; and
closing the at least one shutter through the controlling device when the sensed temperature is higher than the preset temperature or the sensed humidity is outside of the preset humidity range.

6. The method of claim 5, wherein the preset temperature is 25 degrees celsius, and the preset humidity range is 40%-80%.
